(19) United States
(12) Patent Application Publication
(10) Pub. No.: US 2025/0309081 A1
(43) Pub. Date: Oct. 2, 2025

(54) HIGH-FREQUENCY SEMICONDUCTOR PACKAGE

(71) Applicant: Mitsubishi Electric Corporation, Tokyo (JP)

(72) Inventors: Tetsunari SAITO, Tokyo (JP); Shunichi ABE, Tokyo (JP)

(73) Assignee: Mitsubishi Electric Corporation, Tokyo (JP)

(21) Appl. No.: 18/861,040

(22) PCT Filed: Oct. 18, 2022
(86) PCT No.: PCT/JP2022/038656

§ 371 Date: Oct. 28, 2024

(51) Int. Cl. H01L 23/498; H01L 23/00; H01L 23/31; H01L 23/34

(52) U.S. Cl. CPC H01L 23/49827; H01L 23/3107; H01L 23/34; H01L 24/16; H01L 2224/16227

(57) ABSTRACT

A ground terminal (11b), first to third ground patterns (11a,21a,21b), first and second ground via holes (12b,22) and a third connecting member (25) configure an electromagnetic shield structure covering peripheries of a signal terminal (14b), first and second signal patterns (14a,24), a first signal via hole (12a), a semiconductor chip (103) and first and second connecting members (26a,26b).

### FIELD

The present disclosure relates to a high-frequency semiconductor package having an electromagnetic shield.

### BACKGROUND ART

In electronic apparatuses in recent years, high-density mounting of substrate mounting components is desired in response to demands for size reduction and high functionality. As for wireless front-end portions of communication apparatuses such as a smartphone, a cellular phone base station, and a radar apparatus, electromagnetic interference between high-frequency devices due to high-density mounting has particularly become a problem. Thus, a plurality of structures have been suggested in which a high-frequency device alone has an electromagnetic shield. Specifically, a structure has been suggested in which a metal film is formed on an outer side of a sealing resin of a package, the metal film and ground wiring of the package are electrically connected, and an electromagnetic shield is thereby formed (for example, see PTL 1).

### CITATION LIST

### Patent Literature

[PTL 1] JP 2017-022167 A

### SUMMARY OF THE INVENTION

### Problems to be Solved by the Invention

However, in order to form a metal film on an outer side of a sealing resin, a special step such as sputtering, evaporation, or plating becomes necessary. Thus, there has been a problem that a manufacturing cost becomes higher than that of a usual resin-sealed package. Further, there has been a problem that a connection area of the metal film and ground wiring of a package is small and mechanical reliability is low.

The present disclosure has been made for solving the above-described problems, and an object thereof is to obtain a semiconductor apparatus that can improve mechanical reliability.

### Solution to Problem

A high-frequency semiconductor package according to the present disclosure includes: a first substrate including a first base material, a signal terminal and a ground terminal provided on a lower surface of the first base material, a first signal pattern and a first ground pattern provided on an upper surface of the first base material, a first signal via hole passing through the first base material and electrically connecting the signal terminal and the first signal pattern, and a first ground via hole passing through the first base material and electrically connecting the ground terminal and the first ground pattern; a semiconductor chip mounted on an upper surface of the first substrate: a second substrate including a second base material, a second signal pattern and a second ground pattern provided on a lower surface of the second base material, a third ground pattern provided on a whole upper surface of the second base material, and a second ground via hole passing through the second base material and electrically connecting the second ground pattern and the third ground pattern: a first connecting member connecting a signal pad of the semiconductor chip and the second signal pattern: a second connecting member connecting the second signal pattern and the first signal pattern: a third connecting member connecting the first ground pattern and the second ground pattern; and a sealing resin sealing the second substrate, the semiconductor chip and the first to third connecting members, wherein the ground terminal, the first to third ground patterns, the first and second ground via holes and the third connecting member configure an electromagnetic shield structure covering peripheries of the signal terminal, the first and second signal patterns, the first signal via hole, the semiconductor chip and the first and second connecting members.

Another high-frequency semiconductor package according to the present disclosure includes: a first substrate including a first base material, a signal terminal and a ground terminal provided on a lower surface of the first base material, a first signal pattern and a first ground pattern provided on an upper surface of the first base material, a first signal via hole passing through the first base material and electrically connecting the signal terminal and the first signal pattern, and a first ground via hole passing through the first base material and electrically connecting the ground terminal and the first ground pattern: a semiconductor chip mounted on an upper surface of the first substrate: a second substrate including a second base material, a second signal pattern and a second ground pattern provided on a lower surface of the second base material, a third ground pattern provided on a whole upper surface of the second base material, and a second ground via hole passing through the second base material and electrically connecting the second ground pattern and the third ground pattern; a first connecting member connecting a signal pad of the semiconductor chip and the second signal pattern: a second connecting member connecting the second signal pattern and the first signal pattern; and a third connecting member connecting the first ground pattern and the second ground pattern, wherein the ground terminal, the first to third ground patterns, the first and second ground via holes and the third connecting member configure an electromagnetic shield structure covering peripheries of the signal terminal, the first and second signal patterns, the first signal via hole, the semiconductor chip and the first and second connecting members, a cavity is provided on an upper surface side of the first base material, an upper surface of the ground terminal is exposed in the cavity, and the semiconductor chip is mounted on an upper surface of the ground terminal in an internal portion of the cavity.

### Advantageous Effects of Invention

In the high-frequency semiconductor package according to the present disclosure, the ground patterns and the ground via holes of the first substrate and the second substrate cover peripheries of the semiconductor chip and so forth and thereby configure the electromagnetic shield structure. Accordingly, because an electromagnetic shield can be formed by a usual method for manufacturing a resin-sealed package without using a special step such as evaporation, sputtering, or plating, a manufacturing cost of the high-frequency semiconductor package having the electromagnetic shield can be reduced. Further, the ground patterns and the ground via holes except the ground terminals mounted on a mother substrate are positioned on an inside of the sealing resin. Consequently, because the electromagnetic shield structure is not exposed to an outside of the sealing resin, mechanical reliability can be improved.

In another high-frequency semiconductor package according to the present disclosure, the ground patterns and the ground via holes of the first substrate and the second substrate cover the peripheries of the semiconductor chip and so forth and thereby configure the electromagnetic shield structure. Accordingly, because the electromagnetic shield can be formed by a usual method for manufacturing a package without using a special step such as evaporation, sputtering, or plating, the manufacturing cost of the high-frequency semiconductor package having the electromagnetic shield can be reduced. Further, the ground patterns and the ground via holes except the ground terminals mounted on the mother substrate are positioned on an inside of the package. Consequently, because the electromagnetic shield structure is not exposed to an outside of the package, mechanical reliability can be improved. Further, a molding step is not necessary, which contributes to cost reduction. Further, the semiconductor chip is housed in the cavity, which contributes to height reduction of the package.

### BRIEF DESCRIPTION OF THE DRAWINGS

FIG. 1 is a bottom view illustrating a mounting surface of a high-frequency semiconductor package according to a first embodiment.

FIG. 2 is a cross-sectional view taken along I-II in FIG. 1.

FIG. 3 is a bottom view illustrating the second substrate of the high-frequency semiconductor package according to the first embodiment.

FIG. 4 is a top view illustrating the first substrate of the high-frequency semiconductor package according to the first embodiment.

FIG. 5 is a cross-sectional view in which principal components of a high-frequency semiconductor package according to a second embodiment are enlarged.

FIG. 6 is a cross-sectional view illustrating a high-frequency semiconductor package according to a third embodiment.

FIG. 7 is a plan view illustrating the inner layers of the second substrate according to the third embodiment.

FIG. 8 is a cross-sectional view in which principal components of a high-frequency semiconductor package according to a fourth embodiment are enlarged.

FIG. 9 is a plan view in which principal components of a mounting surface of a second substrate of a high-frequency semiconductor package according to the fourth embodiment are enlarged.

FIG. 10 is a cross-sectional view illustrating a high-frequency semiconductor package according to a fifth embodiment.

### DESCRIPTION OF EMBODIMENTS

A high-frequency semiconductor package according to the embodiments of the present disclosure will be described with reference to the drawings. The same components will be denoted by the same symbols, and the repeated description thereof may be omitted.

### First Embodiment

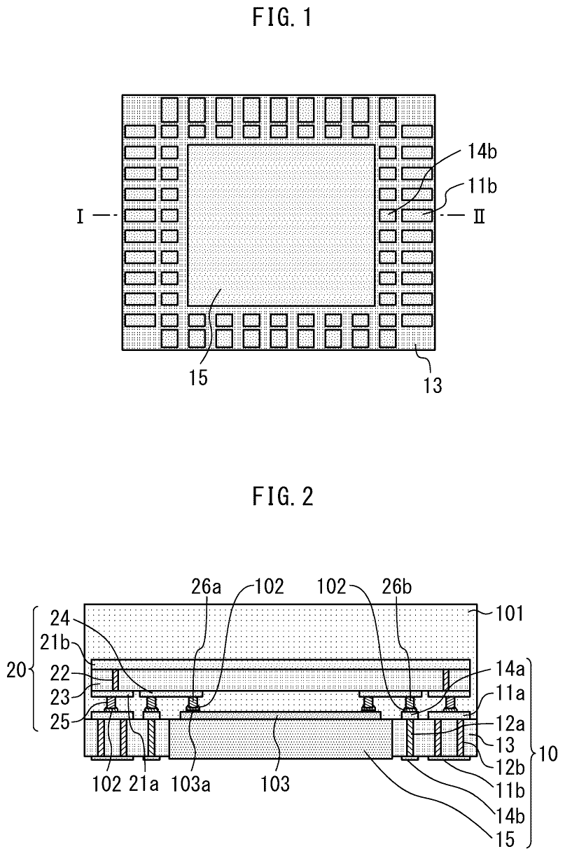

FIG. 1 is a bottom view illustrating a mounting surface of a high-frequency semiconductor package according to a first embodiment. FIG. 2 is a cross-sectional view taken along I-II in FIG. 1. The high-frequency semiconductor package includes a first substrate 10, a second substrate 20, a semiconductor chip 103, and a sealing resin 101.

In the first substrate 10, ground patterns 11a and signal patterns 14a are provided on an upper surface of a first base material 13. Ground terminals 11b and signal terminals 14b are provided on a lower surface of the first base material 13. The signal pattern 14a and the signal terminal 14b are electrically connected by a signal via hole 12a which passes through the first base material 13. The ground pattern 11a and the ground terminal 11b are electrically connected by a ground via hole 12a which passes through the first base material 13. In a planar view, an opening is provided in a central portion of the first base material 13. A heat sink 15 is press-fitted in the opening of the first base material 13. An upper surface of the heat sink 15 is exposed on the upper surface of the base material 13. A lower surface of the heat sink 15 is exposed on the lower surface of the first base material 13.

In the second substrate 20, ground patterns 21a and signal patterns 24 are provided on a lower surface of a second base material 23. A ground pattern 21b covers a whole upper surface of the second base material 23. The ground pattern 21a and the ground pattern 21b are electrically connected by a ground via hole 22 which passes through the second base material 23. A ground metal pillar 25 is formed on the ground pattern 21a, and signal metal pillars 26a and 26b are formed on the signal pattern 24. Each of distal ends of the ground metal pillar 25 and the signal metal pillars 26a and 26b is plated with solder 102.

The second substrate 20 is mounted on the first substrate 10 by flip-chip mounting. By this flip-chip mounting, the signal metal pillar 26a is connected, by the solder 102, with a signal pad 103a formed on an upper surface of the semiconductor chip 103. Further, the signal metal pillar 26b is connected with the signal pattern 14a of the first substrate 10 by the solder 102. Accordingly, the signal pad 103a is electrically connected with the signal metal pillars 26a, the signal patterns 24 of the second substrate 20, the signal metal pillars 26b, the signal patterns 14a of the first substrate 10, and the signal terminals 14b via the signal via holes 12a. As a result, the semiconductor chip 103 can exchange signals with an outside.

Further, by flip-chip mounting, the ground metal pillar 25 is electrically connected with the ground pattern 11a by the solder 102. Accordingly, the ground pattern 21b, the via hole 22, the ground pattern 21a, and the ground metal pillar 25 in the second substrate 20 are electrically connected with the ground pattern 11a, the ground via hole 12b, and the ground terminal 11b in the first substrate 10. As a result, a ground potential of the first substrate 10 and a ground potential of the second substrate 20 become a common potential. This common ground of the first substrate 10 and the second substrate 20 covers peripheries of the semiconductor chip 103, the signal metal pillars 26a and 26b, the signal patterns 14a and 24, the signal via holes 12a, and the signal terminals 14b and thereby configures an electromagnetic shield structure against disturbances.

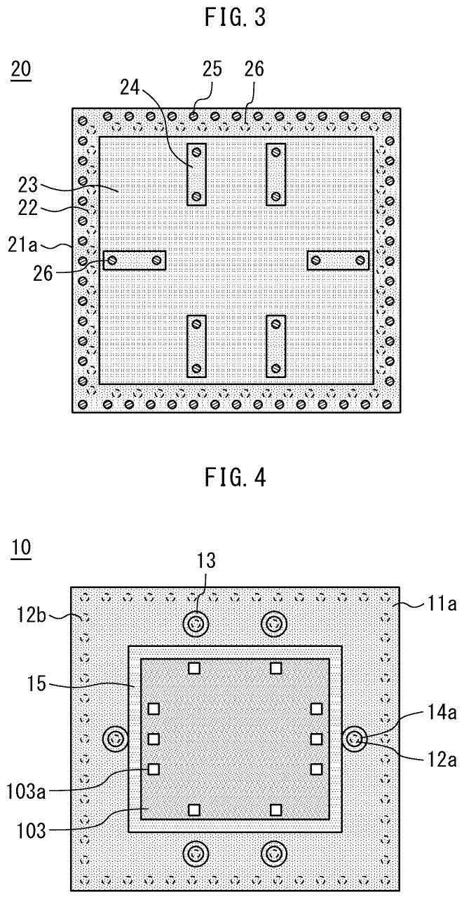

FIG. 3 is a bottom view illustrating the second substrate of the high-frequency semiconductor package according to the first embodiment. The ground via holes 22 and the ground metal pillars 25 are arranged in a ring shape in a periphery portion of the second substrate 20. The signal patterns 24 and the signal metal pillars 26 are arranged in an internal portion of a ring which is formed with the ground via holes 22 and the ground metal pillars 25.

FIG. 4 is a top view illustrating the first substrate of the high-frequency semiconductor package according to the first embodiment. The ground via holes 12b are arranged in a ring shape in a periphery portion of the first substrate 10. The signal patterns 14a, the signal via holes 12a, and the semiconductor chip 103 are arranged in an internal portion of a ring formed with the ground via holes 12b.

As described in the above, in the present embodiment, the ground patterns and the ground via holes of the first substrate 10 and the second substrate 20 cover peripheries of the semiconductor chip 103 and so forth and thereby configure the electromagnetic shield structure. Accordingly, because an electromagnetic shield can be formed by a usual method for manufacturing a resin-sealed package without using a special step such as evaporation, sputtering, or plating, a manufacturing cost of the high-frequency semiconductor package having the electromagnetic shield can be reduced. Further, the ground patterns and the ground via holes except the ground terminals 11b mounted on a mother substrate are positioned on an inside of the sealing resin 101. Consequently, because the electromagnetic shield structure is not exposed to an outside of the sealing resin 101, mechanical reliability can be improved.

Note that in the present embodiment, the heat sink 15 is provided on the assumption of a case where a heat generation amount of the semiconductor chip 103 is large. However, in a case where the heat generation amount of the semiconductor chip 103 does not become a problem, instead of the heat sink 15, general ground via holes and ground patterns may be provided.

Further, the adjacent ground via holes 22 are arranged such that their interval becomes shorter than a half-wavelength λ of a desired frequency, further proper electromagnetic shield performance can thereby be secured at the desired frequency. The same applies to an interval between the adjacent ground via holes 12b and to an interval between the adjacent ground metal pillars 25. Note that a wavelength λ in an internal portion of a dielectric with a relative permittivity er is proportional to the reciprocal of √(εr) with respect to the wavelength λ in a free space.

### Second Embodiment

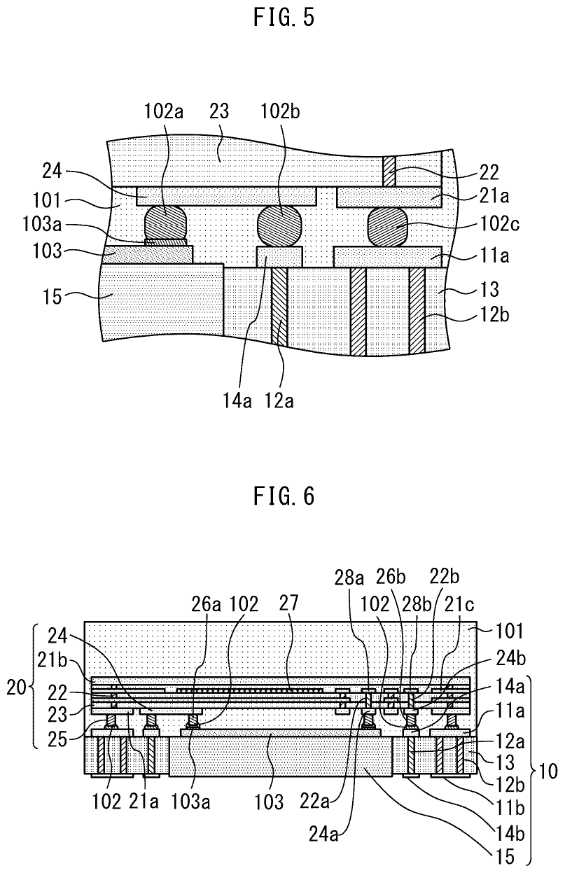

FIG. 5 is a cross-sectional view in which principal components of a high-frequency semiconductor package according to a second embodiment are enlarged. Instead of the signal metal pillars 26a and 26b, the ground metal pillar 25, and the solder 102 in the first embodiment, signal solder balls 102a and 102b and a ground solder ball 102c are used.

By flip-chip mounting, the signal solder ball 102a connects the signal pad 103a of the semiconductor chip 103 with the signal pattern 24 of the second substrate 20. The signal solder ball 102b connects the signal pattern 24 of the second substrate 20 with the signal pattern 14a of the first substrate 10. The ground solder ball 102c connects the ground pattern 11a of the first substrate 10 with the ground pattern 21a of the second substrate 20. Other configurations are similar to those of the first embodiment.

The ground solder ball 102c becomes one part of the electromagnetic shield structure which covers peripheries of the semiconductor chip 103 and so forth. Accordingly, similarly to the first embodiment, the manufacturing cost can be reduced, and mechanical reliability can be improved. Further, by using the signal solder balls 102a and 102b and the ground solder ball 102, height unevenness of the semiconductor chip 103 due to thicknesses of a die-bonding material and warps of the substrates can be absorbed. As a result, mountability by flip-chip mounting is improved.

### Third Embodiment

FIG. 6 is a cross-sectional view illustrating a high-frequency semiconductor package according to a third embodiment. The second substrate 20 is a multilayer substrate, and a harmonic processing filter 27, inner-layer signal patterns 28a and 28b, and a ground pattern 21c are provided in inner layers of the second base material 23. Signal patterns 24a and 24b are provided on a surface of the second substrate 20.

The signal pattern 24a is electrically connected with the signal pad 103a of the semiconductor chip 103 by the signal metal pillar 26a. The signal pattern 24b is electrically connected with the signal pattern 14a of the first substrate 10 by the signal metal pillar 26b. The signal pattern 24a is electrically connected with the inner-layer signal pattern 28a by a signal via hole 22a. The signal pattern 24b is electrically connected with the inner-layer signal pattern 28b by a signal via hole 22b. The ground patterns 21a, 21b, and 21c are electrically connected by the ground via holes 22.

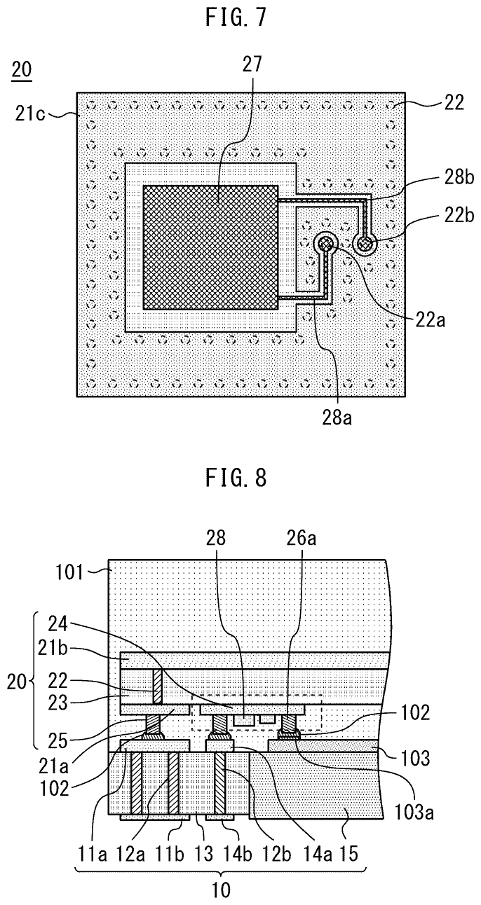

FIG. 7 is a plan view illustrating the inner layers of the second substrate according to the third embodiment. The inner-layer signal patterns 28a and 28b are electrically connected with the harmonic processing filter 27. The ground via holes 22 are arranged in a ring shape in a periphery portion of the second substrate 20. The harmonic processing filter 27, the signal via holes 22a and 22b, and the inner-layer signal patterns 24a and 24b are arranged in an internal portion of a ring formed with the ground via holes 22. Accordingly, the common ground of the first substrate 10 and the second substrate 20 covers peripheries of the harmonic processing filter 27, the signal via holes 22a and 22b, and the inner-layer signal patterns 24a and 24b and thereby configures the electromagnetic shield structure against disturbances.

An output signal of the semiconductor chip 103 passes via the signal metal pillar 26a, the signal pattern 24a, the signal via hole 22a, and the inner-layer signal pattern 28a and is input to the harmonic processing filter 27. An output of the harmonic processing filter 27 passes via the inner-layer signal pattern 28b, the signal via hole 22b, the signal pattern 24b, the signal metal pillar 26b, the signal pattern 14a, and the via hole 12b and is output to the signal terminal 14b.

The semiconductor chip 103 is a semiconductor high frequency amplifier. In general, in the semiconductor high frequency amplifier, harmonics such as a second harmonic and a third harmonic of an operation frequency are generated. In order to remove those harmonics from an output signal, a harmonic processing filter such as a low pass filter or a bandpass filter is provided on an output side of the semiconductor high frequency amplifier. The harmonic processing filter is formed with a line pattern, and when a used frequency is high, the line pattern becomes an antenna and might thereby be subject to electromagnetic interference or give electromagnetic interference to an adjacent device by radiating a signal, conversely. Thus, the harmonic processing filter has to be equipped with electromagnetic shield characteristics against disturbances. As one example of the semiconductor high frequency amplifier, in a case of a configuration in which a high-frequency semiconductor package is installed in a mother board with a multilayer substrate, there are cases where the harmonic processing filter is built in an inner layer of the mother board, its periphery is surrounded by ground patterns or ground via holes of the mother board, and the harmonic processing filter is thereby caused to have the electromagnetic shield characteristics. Because the periphery has to be covered by the ground patterns or ground via holes in order to cause the harmonic processing filter to have the electromagnetic shield characteristics, substrate mounting areas of a plurality of layers are occupied, and design flexibility is influenced.

On the other hand, in the high-frequency semiconductor package according to the present embodiment, the harmonic processing filter 27 having the electromagnetic shield characteristics is provided in the second base material 23. Accordingly, the harmonic processing filter does not have to be built in the inner layers of the substrate of the mother board, and size reduction of the mother board and an improvement in design flexibility of the mother board can be realized.

### Fourth Embodiment

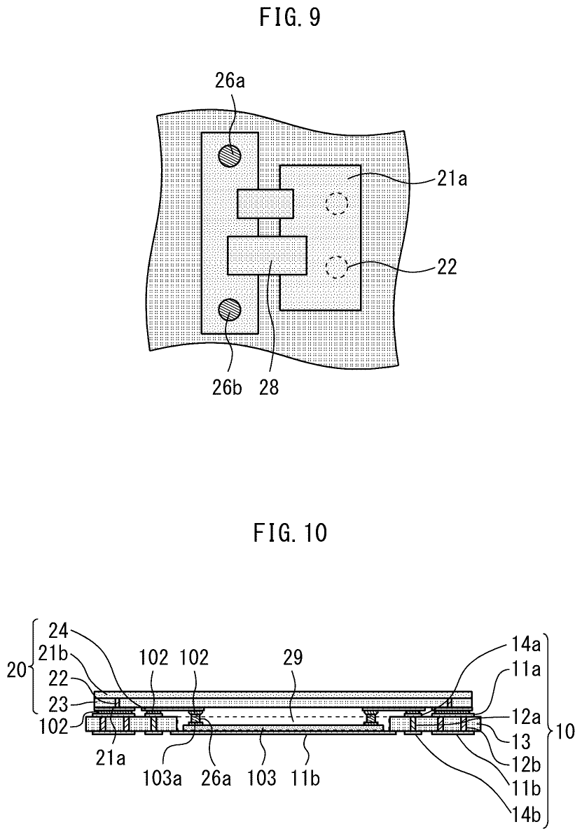

FIG. 8 is a cross-sectional view in which principal components of a high-frequency semiconductor package according to a fourth embodiment are enlarged. FIG. 9 is a plan view in which principal components of a mounting surface of a second substrate of a high-frequency semiconductor package according to the fourth embodiment are enlarged. A passive component 28 is mounted on the surface of the second substrate 20 and is electrically connected between the signal pattern 24 and a ground pattern 21.

The passive component 28 is a capacitor, for example, and serves as a bypass capacitor for the semiconductor chip 103. Note that the passive component 28 is not limited to a capacitor and may be a passive device such as a resistor or a coil. Further, connection of the passive component 28 is not necessarily limited to connection between the signal pattern 24 and the ground pattern 21.

The first substrate 10 is provided with the semiconductor chip 103 with a large area, signal via holes, and ground via holes and has no extra space for mounting the passive component 28. Consequently, it is difficult to mount the passive component 28 in the first substrate 10 while its original substrate size is maintained.

On the other hand, in the second substrate 20, design flexibility of the substrate is high, and the passive component 28 can easily be arranged while the substrate size is maintained. Consequently, in the present embodiment, the bypass capacitor does not have to be mounted on the first substrate 10, which contributes to size reduction of a package size. Further, because a periphery of the passive component 28 is covered by the common ground of the first substrate 10 and the second substrate 20, the passive component 28 has the electromagnetic shield characteristics against disturbance.

### Fifth Embodiment

FIG. 10 is a cross-sectional view illustrating a high-frequency semiconductor package according to a fifth embodiment. A cavity 29 is provided on the upper surface side of the first base material 13. An upper surface of the ground terminal 11b, which is provided in a central portion of the lower surface of the first base material 13, is exposed in the cavity 29. The semiconductor chip 103 is mounted on the upper surface of the ground terminal 11b in an internal portion of the cavity 29. The signal metal pillar 26a is formed on the signal pad 103a of the semiconductor chip 103. By flip-chip mounting, the signal metal pillar 26a is connected with the signal pattern 24 of the second substrate 20 by the solder 102. The signal pattern 24 of the second substrate 20 is connected with the signal pattern 14a of the first substrate 10 by the solder 102. Further, the ground pattern 21a of the second substrate 20 is electrically connected with the ground pattern 11a of the first substrate 10 by the solder 102. As a result, the ground potential of the first substrate 10 and the ground potential of the second substrate 20 become the common potential. This common ground of the first substrate 10 and the second substrate 20 covers peripheries of the semiconductor chip 103, the signal metal pillars 26a, the signal patterns 14a and 24, the signal via holes 12a, and the signal terminals 14b and thereby configures the electromagnetic shield structure against disturbances. In the present embodiment, mold sealing by the sealing resin 101 is not performed. Other configurations are similar to those of the first embodiment. Note that configurations of the second to fourth embodiments may be combined with the present embodiment.

In the present embodiment, the ground patterns and the ground via holes of the first substrate 10 and the second substrate 20 cover the peripheries of the semiconductor chip 103 and so forth and thereby configure the electromagnetic shield structure. Accordingly, because the electromagnetic shield can be formed by a usual method for manufacturing a package without using a special step such as evaporation, sputtering, or plating, the manufacturing cost of the high-frequency semiconductor package having the electromagnetic shield can be reduced. Further, the ground patterns and the ground via holes except the ground terminals 11b mounted on the mother substrate are positioned on an inside of the package. Consequently, because the electromagnetic shield structure is not exposed to an outside of the package, mechanical reliability can be improved. Further, a molding step is not necessary, which contributes to cost reduction. Further, the semiconductor chip 103 is housed in the cavity 29, which contributes to height reduction of the package.

### REFERENCE SIGNS LIST

10 first substrate; 11a ground pattern (first ground pattern); 11b ground terminal; 12a signal via hole (first signal via hole); 12b ground via hole (first ground via hole); 13 first base material; 14a signal pattern (first signal pattern); 14b signal terminal; 15 heat sink; 20 second substrate; 21a ground pattern (second ground pattern); 21b ground pattern (third ground pattern); 22 ground via hole (second ground via hole); 22a signal via hole (second signal via hole); 22b signal via hole (third signal via hole); 23 second base material; 24 signal pattern (second signal pattern); 24a signal pattern (third signal pattern); 24b signal pattern (fourth signal pattern); 25 ground metal pillar (third connecting member); 26a signal metal pillar (first connecting member); 26b signal metal pillar (second connecting member); 27 harmonic processing filter; 28 passive component; 29 cavity; 101 sealing resin; 102a signal solder ball (first connecting member); 102b signal solder ball (second connecting member); 102c ground solder ball (third connecting member); 103 semiconductor chip; 103a signal pad

1. A high-frequency semiconductor package comprising:
a first substrate including a first base material, a signal terminal and a ground terminal provided on a lower surface of the first base material, a first signal pattern and a first ground pattern provided on an upper surface of the first base material, a first signal via hole passing through the first base material and electrically connecting the signal terminal and the first signal pattern, and a first ground via hole passing through the first base material and electrically connecting the ground terminal and the first ground pattern;
a semiconductor chip mounted on an upper surface of the first substrate;
a second substrate including a second base material, a second signal pattern and a second ground pattern provided on a lower surface of the second base material, a third ground pattern provided on a whole upper surface of the second base material, and a second ground via hole passing through the second base material and electrically connecting the second ground pattern and the third ground pattern;
a first connecting member connecting a signal pad of the semiconductor chip and the second signal pattern;
a second connecting member connecting the second signal pattern and the first signal pattern;
a third connecting member connecting the first ground pattern and the second ground pattern; and
a sealing resin sealing the second substrate, the semiconductor chip and the first to third connecting members,
wherein the ground terminal, the first to third ground patterns, the first and second ground via holes and the third connecting member configure an electromagnetic shield structure covering peripheries of the signal terminal, the first and second signal patterns, the first signal via hole, the semiconductor chip and the first and second connecting members.

2. The high-frequency semiconductor package according to claim 1, wherein the first to third connecting members include metal pillars.

3. The high-frequency semiconductor package according to claim 1, wherein the first to third connecting members are solder balls.

4. The high-frequency semiconductor package according to claim 1, wherein the second signal pattern includes a third signal pattern electrically connected with the signal pad of the semiconductor chip by the first connecting member, and a fourth signal pattern electrically connected with the first signal pattern by the second connecting member, and
the second substrate includes a harmonic processing filter provided in an inner layer of the second base material, a second signal via hole electrically connecting the third signal pattern and the harmonic processing filter, and a third signal via hole electrically connecting the fourth signal pattern and the harmonic processing filter.

5. The high-frequency semiconductor package according to claim 1, further comprising a passive component mounted on a lower surface of the second substrate and electrically connected between the second signal pattern and the second ground pattern.

6. The high-frequency semiconductor package according to claim 1, wherein an opening is provided in a central portion of the first base material,
a heat sink is press-fitted in the opening, and
the semiconductor chip is mounted on the heat sink.

7. A high-frequency semiconductor package comprising:
a first substrate including a first base material, a signal terminal and a ground terminal provided on a lower surface of the first base material, a first signal pattern and a first ground pattern provided on an upper surface of the first base material, a first signal via hole passing through the first base material and electrically connecting the signal terminal and the first signal pattern, and a first ground via hole passing through the first base material and electrically connecting the ground terminal and the first ground pattern;
a semiconductor chip mounted on an upper surface of the first substrate;
a second substrate including a second base material, a second signal pattern and a second ground pattern provided on a lower surface of the second base material, a third ground pattern provided on a whole upper surface of the second base material, and a second ground via hole passing through the second base material and electrically connecting the second ground pattern and the third ground pattern;
a first connecting member connecting a signal pad of the semiconductor chip and the second signal pattern;
a second connecting member connecting the second signal pattern and the first signal pattern; and
a third connecting member connecting the first ground pattern and the second ground pattern,
wherein the ground terminal, the first to third ground patterns, the first and second ground via holes and the third connecting member configure an electromagnetic shield structure covering peripheries of the signal terminal, the first and second signal patterns, the first signal via hole, the semiconductor chip and the first and second connecting members,
a cavity is provided on an upper surface side of the first base material,
an upper surface of the ground terminal is exposed in the cavity, and
the semiconductor chip is mounted on an upper surface of the ground terminal in an internal portion of the cavity.
